(19) United States
(12) Patent Application Publication
(10) Pub. No.: US 2006/0163490 A1
(43) Pub. Date: Jul. 27, 2006

(54) Ion implantation cooling system

(75) Inventors: Daniel Tang, San Jose, CA (US); Jiong Chen, San Jose, CA (US); Wei-Cheng Lin, HsinChu County (TW)

Correspondence Address: BIRCH STEWART KOLASCH & BIRCH, PO BOX 747, FALLS CHURCH, VA, 22040-0747, US

(73) Assignee: Advanced Ion Beam Technology Inc.

(21) Appl. No.: 11/334,429

(22) Filed: Jan. 19, 2006

Related U.S. Application Data
(60) Provisional application No. 60/645,007, filed on Jan. 21, 2005.

(51) Int. Cl. H01J 37/20

(52) U.S. Cl. 250/443.1

(57) ABSTRACT

An ion implantation cooling system at least comprises a semiconductor substrate utilized as the ion implantation substrate, a Pelier thermoelectric pump connected with the semiconductor substrate for heat irradiation during the ion implantation, and a heatsink connected to the Pelier thermoelectric pump for heat irradiation from a hot Pelier surface during the ion implantation. The cooling system is to employ the Pelier thermoelectric pump enabling the semiconductor substrate and the semiconductor substrate surface being at a temperature lower than that of the heatsink, so the object of proceeding ion implanting at a lower temperature can be achieved thereby.

### CROSS-REFERENCE TO RELATED APPLICATIONS

This non-provisional application claims priority under 35 U.S.C. § 119(e) on Pat. Application No(s). 60/645,007 filed in the United States on Jan. 21, 2005, the entire contents of which are hereby incorporated by reference.

### BACKGROUND OF THE INVENTION

1. Field of the Invention

The invention relates to a semiconductor wafer processing system, and more particularly, to an ion implantation cooling system for semiconductor wafer processing.

2. Related Art

Ion implantation has become a standard technique for introducing impurities into semiconductor wafers nowadays. Semiconductor wafers kept at low temperature during ion implantation can bring advantages for making semiconductor devices, such as the characteristics of low current leakage, low parasitic capacitor, and low parasitic resistance, so that the semiconductor devices has high reliability and low distortion output signal after long term operating at high temperature.

It is worth to mention that crystal defect (or crystal dislocation) caused by improper heating process will result in electric charges accumulated and buried in the vicinity of different crystal structure of the semiconductor substrate led to the problems of current leakage, parasitic capacitor, and parasitic resistance in the semiconductor device. In addition, if the semiconductor device is operated at high temperature, it will soon be damaged and lost its function. Especially, the problems get worse in case of large scale integration (LSI) or very large scale integration (VLSI) devices, which virtually disallow unexpected leakage current, parasite capacitor, and parasitic resistance in the system.

This problem is enhanced in the fabrication of large scale integration (LSI) or very large scale integration (VLSI) devices since a great number of complicated processing steps must be applied in serious. During the wafer processing, plenty of impurities, conducting layers, insulating layers are introduced, and during ion implantation, momentum energetic ions bombard into the bulk of semiconductor wafers as means to embed them into the crystal lattice of the semiconductor material. As energetic ions implanted into the bulk of semiconductor wafer, a great amount of heat is generated by the atomic collisions. At this point, it is even more important to keep semiconductor substrates at an expected low temperature for the wafer quality during ion implantation.

Referring to FIG. 1, the explanation view of conventional technology of ion implantation cooling system is shown. The conventional cooling system consists of a semiconductor substrate 20, a static electricity chuck (E-chuck) 30, and a liquid-cooled heatsink 40. The semiconductor substrate 20 is placed upon the E-chuck 30 as ion implantation substrate. An E-chuck 30 is to firmly hold the semiconductor substrate 20 upon the liquid-cooled heatsink 40 by way of static electric induction; Moreover, air-blowing is utilized in between the semiconductor substrate 20 and the liquid-cooled heatsink 40 to irradiate the heat from the semiconductor substrate 20 to the liquid-cooled heatsink 40 so as to control the surface temperature rising. However, in this way, the temperature of semiconductor substrate is unable to lower than that of the heatsink, so the object of proceeding ion implanting at a more lower temperature, such as water freezing point 0□, can't be achieved thereby.

As the reference document 1 of 2004 international ion implanting (IIT) meeting in Taiwan, Bae reported lowering wafer temperature by 5□ during ion implantation can reduce fluorine concentration in an amorphous/crystal interface. The reduction is because the low wafer temperature reduces self-annealing effects during the implantation. However, the major semiconductor manufacturers are requesting for wafer temperature below water freezing point during the implantation.

In U.S. Pat. No. 6,570,169, Suguro stated that the Si substrate surface was kept at −60□ or less during the ion implanting conducted by him. But, Suguro didn't mention how to cool wafers to the required temperature during the ion implantation. The current wafer cooling methods adopted in implantation equipment are not unable to satisfy this temperature requirement.

In U.S. Pat. No. 5,338,940, Takeyama introduced a contactless cooling method for ion beam implantation. The wafer disk is supported by electromagnetism and an annular groove providing a heat radiation zone is formed under the wafer receiving faces of the wafer disk that holds plausible wafers. A cooling plate cooled to a temperature close to the temperature of liquid nitrogen is inserted into the groove in a contactless manner so that the wafer disk is cooled by heat radiation. The inter face of the annular groove and the outer surface of the cooling plate can be electrolyzed or coat a black heat-absorbing painting so as to enhance the ability of heat absorption. In the absence of any area of physical contact in mechanisms for axially supporting and cooling the wafer disk, ions can be implanted in low dose into wafers on a fast rotating disk while the quality of the wafers after implantation is improved. In addition, heat transfer between the wafer and the cooling plate is via heat radiation that has very low heat-removing rates, so it is not suitable in high current ion implantation applications.

The conventional methods used in ion implanter can also be seen in U.S. Pat. No. 4,282,924. A wafer is mechanically hold on a platen with a narrow gap between them and a small amount of gas is injected into the gap as means to carries heat from the wafer to the platen body. The platen body is cooled by water with room temperature or chilled water. However, the limitation of this method is that the lowest temperature can only reach to 0□.

### SUMMARY OF THE INVENTION

With regard to the weak points of the conventional technology, the present invention discloses a method for cooling the interface between the substrate and the body of substrate holder or platen. A thermoelectric cooler is used at this occasion thereby. The thermoelectric cooler is based on Pelier effect. When a current flows through two dissimilar metals or semiconductors (n-type or p-type) connected to each other by two junctions (Pelier junctions), the current drives the heat transferring from one junction to the other One Pelier surface will be cooled off while the other one will be heated up.

The Pelier cooler can be sandwiched in between the substrate and the platen. The cool surface of the cooler is bonded to E-chuck. Air-blowing is utilized in between the semiconductor substrate and the cool surface to irradiate the heat from the semiconductor substrate to the platen so as to control the surface temperature rising. On the other hand, the hot surface of cooler is bonded to platen (serve as a heatsink) and the hot surface is chilled with water. The maximum temperature difference between cool and hot surfaces of a Pelier cooler was reported to be 70□. A series of Pelier cooler can be bonded in series to further reduce the cool surface temperature. The heat removal rate is reported to be 12 W/cm2. The heat irradiated to substrates during implantation is around 2W/cm2.

The Pelier cooler is composed of solid blocks and the above system is compatible in vacuum system. A special designed multi-stage Pelier cooler is able to cool substrate holder or platen as cool as −110□ from room ambient. In compare with the conventional technology herebefore, the Pelier has the following advantages:

1. Reduced volume, size, and weight; Excellent miniaturization

2. Solid state reliability means no moving parts to wear out; Maintenance free; High resistance to shock and vibration; No acoustical or electrical noise

3. Precision temperature control above or below ambient by virtue of Pelier effect

4. Environmentally friendly: no toxic gases or refrigerant required

5. Compatible with fan cooled and liquid-cooled heatsink

### BRIEF DESCRIPTION OF THE DRAWINGS

The invention will become more fully understood from the detailed description given hereinbelow. However, the following description is for purposes of illustration only, and thus is not limitative of the invention, wherein

FIG. 1 is the cross sectional view of conventional technology;

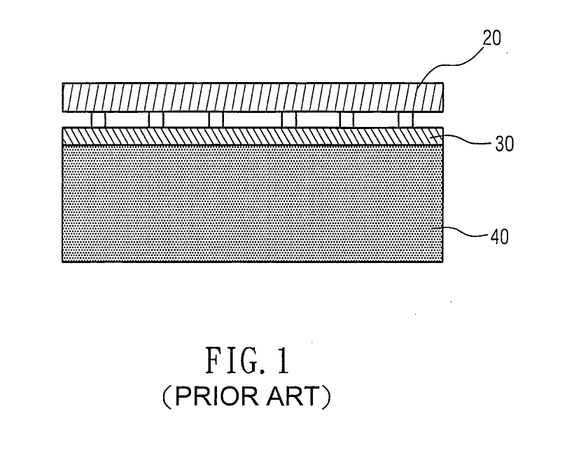

FIG. 2 is the cross sectional view of the first embodiment of the invention;

FIG. 3 is the cross sectional view of the second embodiment of the invention;

FIG. 4 is the cross sectional view of the third embodiment of the invention;

FIG. 5 is the cross sectional view of the fourth embodiment of the invention;

FIG. 6 is the cross sectional view of the fifth embodiment of the invention; and

FIG. 7 is the cross sectional view of the invention in physics fundamental.

### DETAILED DESCRIPTION OF THE INVENTION

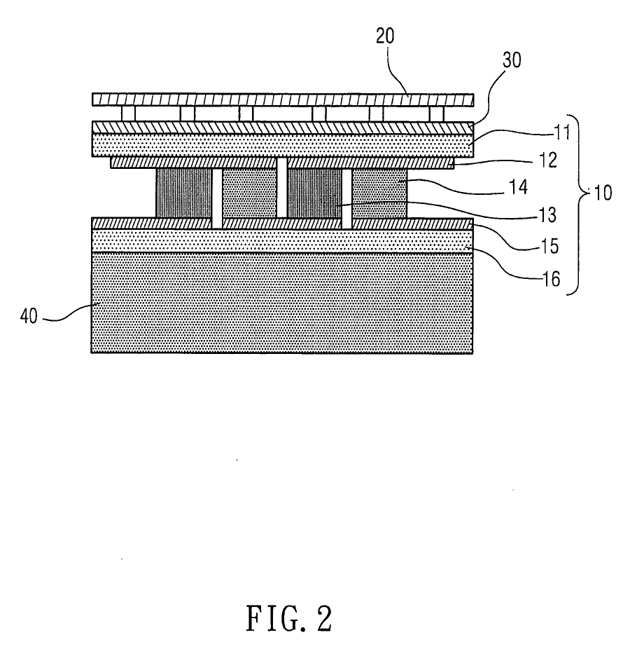

Referring to FIG. 2 is the representative view of the present application. First, the system comprises a liquid-cooled heatsink 40, a Pelier thermoelectric pump 10, an E-chuck 30, and a semiconductor substrate 20. The heatsink 40 is placed beneath the Pelier thermoelectric pump 10 for heat irradiation from a hot Pelier surface 16 during the ion implantation.

The Pelier thermoelectric pump 10 is employed and placed in between the heatsink 40 and the E-chuck 30, wherein the Pelier thermoelectric pump 10 comprises a hot Pelier surface 16, a cool Pelier surface 11. The hot Pelier surface 16 is placed in between the heatsink 40 and the cool Pelier surface 11 and made of high specific heat materials like as ceramic for heat irradiation from the cool Pelier surface 11. On the other hand, the cool Pelier surface 11 is placed in between the hot Pelier surface 16 and the E-chuck 30 and made of high specific heat materials like as ceramic for heat irradiation from an E-chuck 30. A plurality of pairs of N-type semiconductors 13 and P-type semiconductors 14 or a plurality of pairs of dissimilar metals is placed in between the hot Pelier surface 16 and the cool Pelier surface 11, thereby; the surfaces are electrically connected to each other.

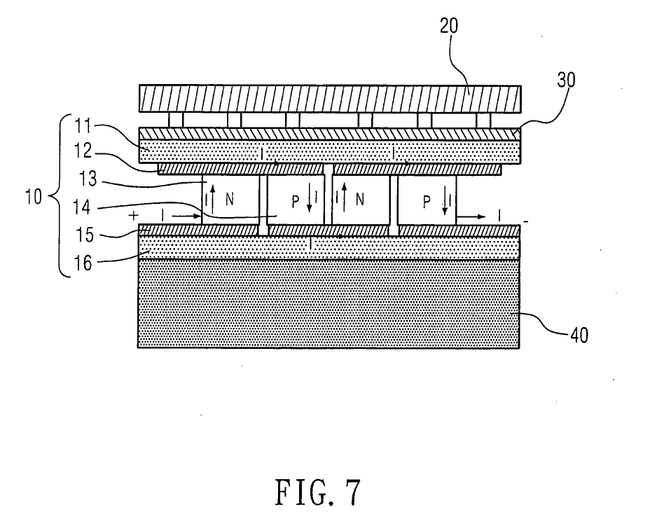

The fundamental of the Pelier thermoelectric pump 10 being applied is detailed as below referring to FIG. 7: A direct current “I” flows from a Pelier connector 15 at N-type semiconductors 13 (“+” as anode) to a Pelier connector 12 at P-type semiconductors 14 (“−” as cathode). The flowing of current is indicated as arrows as shown in FIG. 7. Based on the Pelier effect, the electric charge takes away heat from a cool Pelier surface 11 by way of the direct current, and then the heat is released at hot Pelier surface 16. The heat generated by ion bombarding substrate bulk is transferred from the semiconductor substrate 20 to the hot Pelier surface 16 by way of the cool Pelier surface 11 and the E-chuck 30 afterwards.

Furthermore, the E-chuck 30 is placed in between the cool Pelier surface 11 and the semiconductor substrate 20 for firmly holding the semiconductor substrate 20 upon the Pelier thermoelectric pump 10 by way of electric induction; moreover, air-blowing is utilized in between the cool Pelier surface 11 and the semiconductor substrate 20 to further irradiate the heat from the semiconductor substrate 20 to the cool Pelier surface 11 so as to control the surface temperature rising.

The semiconductor substrate 20 is placed upon the E-chuck 30 as the ion implantation substrate; In summarized of the abovementioned cooling system, making use of Pelier thermoelectric pump 10 is capable of fast heat irradiation and cooling the semiconductor substrate 20 being at a temperature lower than that of the heatsink, so the object of proceeding ion implanting at a lower temperature can be achieved thereby.

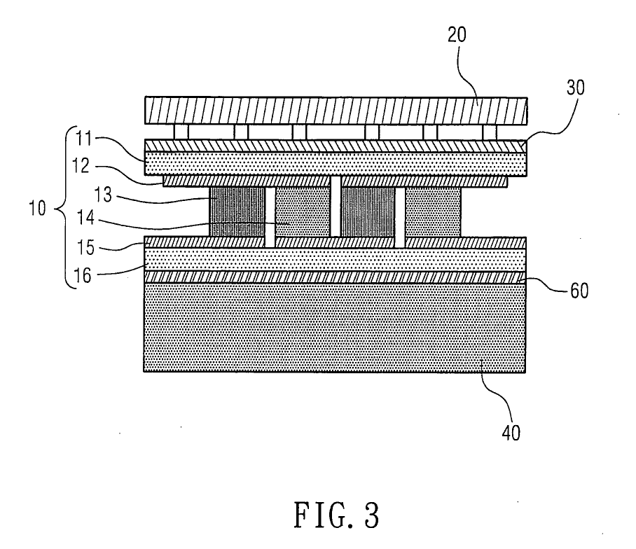

Referring to FIG. 3, a liquid-cooled heatsink 40, a thermal conducting plate 60 of hot Pelier surface, a Pelier thermoelectric pump 10, an E-chuck 30, and a semiconductor substrate 20 are provided. The heatsink 40 may be a water-cooled heatsink, a refrigerant-cycling-cooled heatsink, or a liquid-nitrogen-cooled heatsink and is placed beneath the thermal conducting plate 60 of hot Pelier surface 16 for heat irradiation from the thermal conducting plate 60 of hot Pelier surface 16 during the ion implantation.

The Pelier thermoelectric pump 10 is placed in between the thermal conducting plate 60 of hot Pelier surface 16 and the Pelier thermoelectric pump 10, and it comprises a hot Pelier surface 16 and a cool Pelier surface 11.

The E-chuck 30 is placed in between the cool Pelier surface 11 and the semiconductor substrate 20 for firmly holding the semiconductor substrate 20 upon the Pelier thermoelectric pump 10 by way of electric induction; moreover, air-blowing is utilized in between the cool Pelier surface 11 and the semiconductor substrate 20 to further irradiate the heat from the semiconductor substrate 20 to the cool Pelier surface 11 so as to control the surface temperature rising. In addition, the semiconductor substrate 20 is placed upon the E-chuck 30 as the ion implantation substrate. In summarized of the abovementioned cooling system, making use of the thermal conducting plate 60 of hot Pelier surface 16 is capable of fast heat irradiation and cooling the semiconductor substrate 20 being at a temperature lower than that of the heatsink, so the object of proceeding ion implanting at a lower temperature can be achieved thereby.

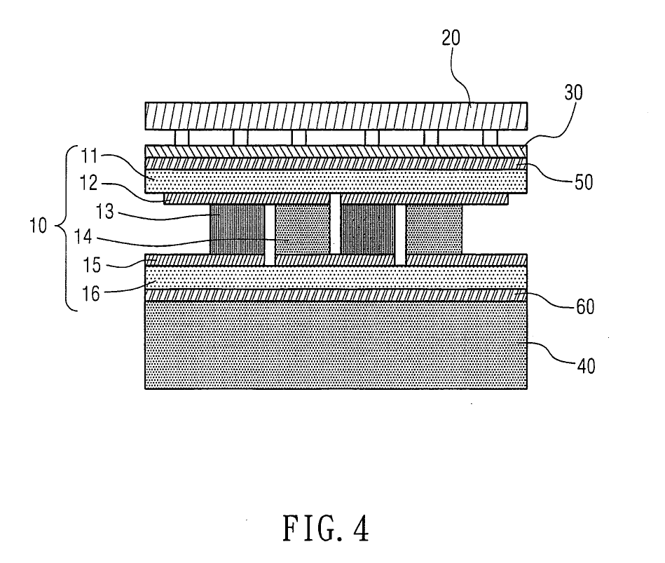

Referring to FIG. 4, a liquid-cooled heatsink 40, a thermal conducting plate 60 of hot Pelier surface 16, a Pelier thermoelectric pump 10, a thermal conducting plate 50 of the cool Pelier surface 11, an E-chuck 30, and a semiconductor substrate 20 are provided. The heatsink 40 may be a water-cooled heatsink, a refrigerant-cycling-cooled heatsink, or a liquid-nitrogen-cooled heatsink and is placed beneath the thermal conducting plate 60 of hot Pelier surface 16 for heat irradiation from the thermal conducting plate 60 of hot Pelier surface 16 during the ion implantation. The thermal conducting plate 60 of the hot Pelier surface 16 is placed in between the heatsink 40 and the hot Pelier surface 16 for even fast heat irradiation from the hot Pelier surface 16 to the heatsink 40 during the ion implantation.

The Pelier thermoelectric pump 10 is placed in between the thermal conducting plate 60 of hot Pelier surface 16 and the thermal conducting plate 50 of cool Pelier surface 11, wherein the Pelier thermoelectric pump 10 comprises a hot Pelier surface 16 and a cool Pelier surface 11.

The thermal conducting plate 50 of cool Pelier surface 11 is made of a metal and placed in between the cool Pelier surface 11 and the E-chuck 30 for fast heat irradiation from the cool Pelier surface 11 to the E-chuck 30 during the ion implantation. The E-chuck 30 is placed in between the thermal conducting plate 50 and the semiconductor substrate 20 for firmly holding the semiconductor substrate 20 upon the Pelier thermoelectric pump 10 by way of electric induction. In addition, the semiconductor substrate 20 is placed upon the E-chuck 30 as the ion implantation substrate. In summarized of the abovementioned cooling system, making use of the thermal conducting plate 60 of hot Pelier surface 16 and the thermal conducting plate 50 of cool Pelier surface 11 is capable of fast heat irradiation and cooling the semiconductor substrate 20 being at a temperature lower than that of the heatsink, so the object of proceeding ion implanting at a lower temperature can be achieved thereby.

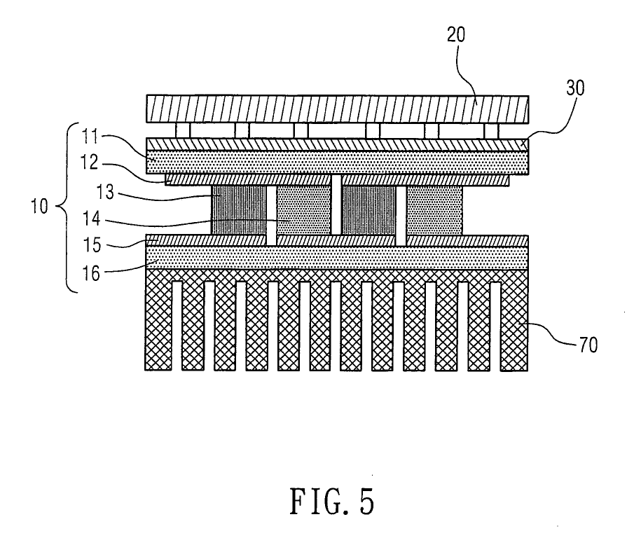

Referring to FIG. 5, a mechanical heatsink or heat dissipating plate 70, a Pelier thermoelectric pump 10, an E-chuck 30, a semiconductor substrate 20 are provided. The mechanical heatsink or heat dissipating plate 70 is placed beneath the Pelier thermoelectric pump 10 for heat irradiation from the hot Pelier surface 16 during the ion implantation.

The Pelier thermoelectric pump 10 is placed in between the heat dissipating plate 70 and the E-chuck 30, wherein the Pelier thermoelectric pump 10 comprises a hot Pelier surface 16 and a cool Pelier surface 11.

The E-chuck 30 is placed in between the cool Pelier surface 11 and the semiconductor substrate 20 for firmly holding the semiconductor substrate 20 upon the Pelier thermoelectric pump 10 by way of electric induction. The semiconductor substrate 20 is placed upon the E-chuck 30 as the ion implantation substrate. In summarized of the abovementioned cooling system, making use of Pelier thermoelectric pump 10 is capable of fast heat irradiation and cooling the semiconductor substrate 20 being at a temperature lower than that of the heatsink, so the object of proceeding ion implanting at a lower temperature can be achieved thereby.

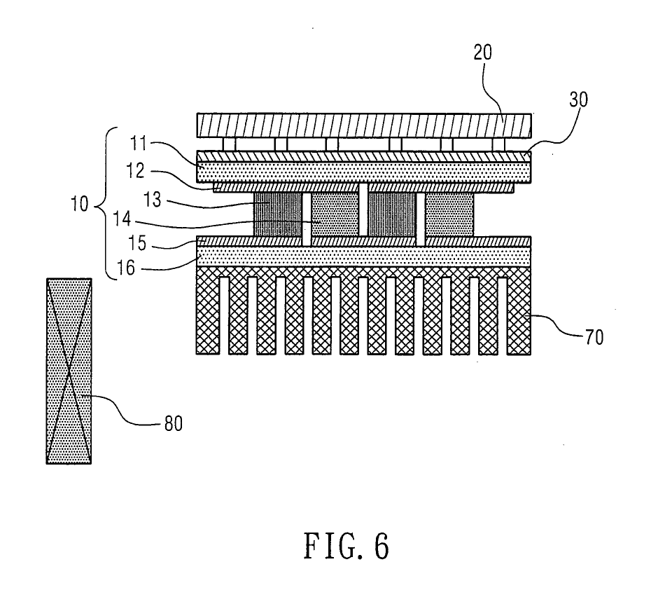

Referring to FIG. 6, a mechanical heatsink or heat dissipating plate 70 having a fan 80, a Pelier thermoelectric pump 10, an E-chuck 30, and a semiconductor substrate 20 are provided. The mechanical heatsink or heat dissipating plate 70 is placed beneath the Pelier thermoelectric pump 10 for heat irradiation from a hot Pelier surface 16 during the ion implantation. The fan 80 is placed in the neighborhood of heat dissipating plate 70 having the ability to force ambient air convection to enhance the cooling performance of the mechanical heatsink or heat dissipating plate 70.

Te Pelier thermoelectric pump 10 is placed in between the heat dissipating plate 70 and the E-chuck 30, wherein the Pelier thermoelectric pump 10 comprises a hot Pelier surface 16 and a cool Pelier surface 11.

The E-chuck 30 is placed in between the cool Pelier surface 11 and the semiconductor substrate 20 for firmly holding the semiconductor substrate 20 upon the Pelier thermoelectric pump 10 by way of electric induction. The semiconductor substrate 20 is placed upon the E-chuck 30 as the ion implantation substrate. In summarized of the abovementioned cooling system, making use of Pelier thermoelectric pump 10 is capable of fast heat irradiation and cooling the semiconductor substrate 20 being at a temperature lower than that of the heatsink, so the object of proceeding ion implanting at a more lower temperature can be achieved thereby. More important is the temperature of the semiconductor substrate can reach to under 0□ during the ion implantation after the present invention is applied.

There has been described what are presently considered to be preferred embodiments of the present invention, it will be understood by those skilled in the art that various changes and modifications may be made without departing from the scope of the invention. In addition many modifications may be made to a particular situation or material to the teaching of the present invention without departing the scope thereof. Therefore it is intended that this invention not be limited to the particular embodiments disclosed as the best mode contemplated for carrying out this invention, but that the invention include all embodiments being within the scope of the appended claims.

What is claimed is:

1. An ion implantation cooling system, at least comprising:
a semiconductor substrate wherein the semiconductor substrate is utilized as the ion implantation substrate;
a Pelier thermoelectric pump is connected to the semiconductor substrate for heat irradiation during the ion implantation; and
a heatsink is connected with the Pelier thermoelectric pump for heat irradiation during the ion implantation;
wherein the Pelier thermoelectric pump comprises a hot Pelier surface and a cool Pelier surface, the semiconductor substrate being firmly held with the cool Pelier surface and the hot Pelier surface being connected with the heatsink.

2. The ion implantation cooling system of claim 1, wherein the heatsink is selected from the group consisting of water-cooled heatsink, refrigerant-cycling-cooled heatsink, and liquid-nitrogen-cooled heatsink.

3. The ion implantation cooling system of claim 1, wherein the heatsink is a mechanical heatsink or a heat dissipating plate.

4. The ion implantation cooling system of claim 3, wherein the mechanical heatsink includes a fan.

5. The ion implantation cooling system of claim 1, wherein the connecting surface of the hot Pelier surface and the heatsink is made of metal.

6. The ion implantation cooling system of claim 1, wherein the connecting surface of the cool Pelier surface and the heatsink is made of metal, and the connecting surface of the hot Pelier surface and the heatsink is made of metal as well.

7. The ion implantation cooling system of claim 1, wherein the temperature of the semiconductor substrate is under 0□ during the ion implantation.
